(19) United States
(12) Patent Application Publication
(10) Pub. No.: US 2004/0027851 A1
(43) Pub. Date: Feb. 12, 2004

(54) Memory cell and circuit with multiple bit lines

(75) Inventor: Thomas C.J. Lai, Taipei City (TW)

Correspondence Address: Ladas & Parry, 26 West 61st Street, New York, NY, 10023, US

(73) Assignee: WINBOND ELECTRONICS CORPORATION

(21) Appl. No.: 10/329,259

(22) Filed: Dec. 23, 2002

(30) Foreign Application Priority Data
Aug. 9, 2002 (TW) 091118067

(51) Int. Cl. G11C 11/24

(52) U.S. Cl. 365/149

(57) ABSTRACT

The present invention discloses a memory cell and circuit with multiple bit lines, which can allow two word lines and bit lines in the same memory block to access different memory cells in the memory block. The memory cell with multiple bit lines according to the present invention comprises a capacitor, at least two transistor switches, at least two word line terminals, and at least two bit line terminals. At least two transistor switches are connected at one end to the capacitor. At least two word line terminals are used to control the connection between the two transistor switches. At least two bit line terminals are connected to the other end of the two transistor switches opposite the capacitor.

### BACKGROUND OF THE INVENTION

(A) Field of the Invention

The present invention relates to memory cells and a memory circuit, more specifically to memory cells and a memory circuit with multiple bit lines.

(B) Description of Related Art

FIG. 1 illustrates a conventional memory cell 10, which comprises a capacitor 11, a cell plate voltage 12, a MOS transistor 13, a bit line terminal 14 connected to the drain of the MOS transistor 13, and a word line terminal 15 connected to the gate of the MOS transistor 13. Before sending a memory read command, the word line terminal 14 is at a discharged state or fixed at a specific voltage. When the memory read command is decoded and sent to the memory cell 10, the word line terminal 15 can be enabled and the channel of the MOS transistor 13 is opened, so that the charge on the capacitor 11 is connected to the bit line terminal 14. After executing the memory read command, the charge will be inputted into the capacitor 11 from the bit line terminal 14 for compensating the logical voltage.

The memory circuit is composed of memory cells 10, as shown in FIG. 2. The memory circuit 20 includes a plurality of memory cells 10 arranged in a matrix form. The memory cells 10 in vertical adjacency share the same bit line, and the memory cells 10 in horizontal adjacency share the same word line. Owing to the above connection structure, only one memory cell within the plurality of memory cells connected by any bit line of the memory circuit 20 is allowed for connection, and the logical voltage of the memory cells is connected to the bit line. If there are two or more memory cells connected simultaneously, the logical voltages of the two will contradicted, and possibly caused some damages to the stored information.

Currently, however for the product application of high-speed memory, because of various limitations of the conventional design, the market requirement cannot be satisfied.

According to the existing problems in the prior art, the present invention discloses novel memory cells and a memory circuit with multiple bit lines to overcome the above-mentioned problems.

### SUMMARY OF THE INVENTIION

The object of the present invention is to provide memory cells and a memory circuit with multiple bit lines for high-speed application.

To this end, the present invention discloses a memory cell and circuit with multiple bit lines, which can allow two word lines and bit lines in the same memory block to access different memory cells in the memory block. Thus, the operation efficiency of the memory can be improved.

The memory circuit with multiple bit lines can be applied to the dynamic random access memory (DRAM), the static random access memory (SRAM), the SRAM interface implemented with DRAM, or the DRAM with hidden external refresh commands.

The memory cell with multiple bit lines according to the present invention comprises a capacitor, at least two transistor switches, at least two word line terminals, and at least two bit line terminals. At least two transistor switches are connected at one end to the capacitor. At least two word line terminals are used to control the connection between the two transistor switches. At least two bit line terminals are connected to the other end of the two transistor switches opposite the capacitor.

The memory circuit with multiple bit lines according to the present invention comprises a memory cell with multiple bit lines in an m×n matrix arrangement, 2×m bit lines and 2×n word lines. The 2×m bit lines are electrically connected to the bit line terminals of the memory cell with multiple bit lines in vertical adjacency. The 2×n word lines are electrically connected to the word line terminals of the memory cell with multiple bit lines in horizontal adjacency.

### BRIEF DESCRIPTION OF THE DRAWINGS

The present invention will be described according to the appended drawings in which:

FIG. 1 shows a prior art memory unit;

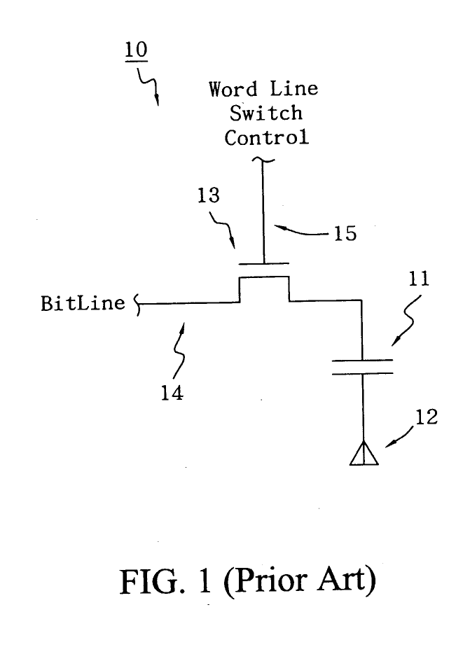

FIG. 2 shows a prior art memory circuit;

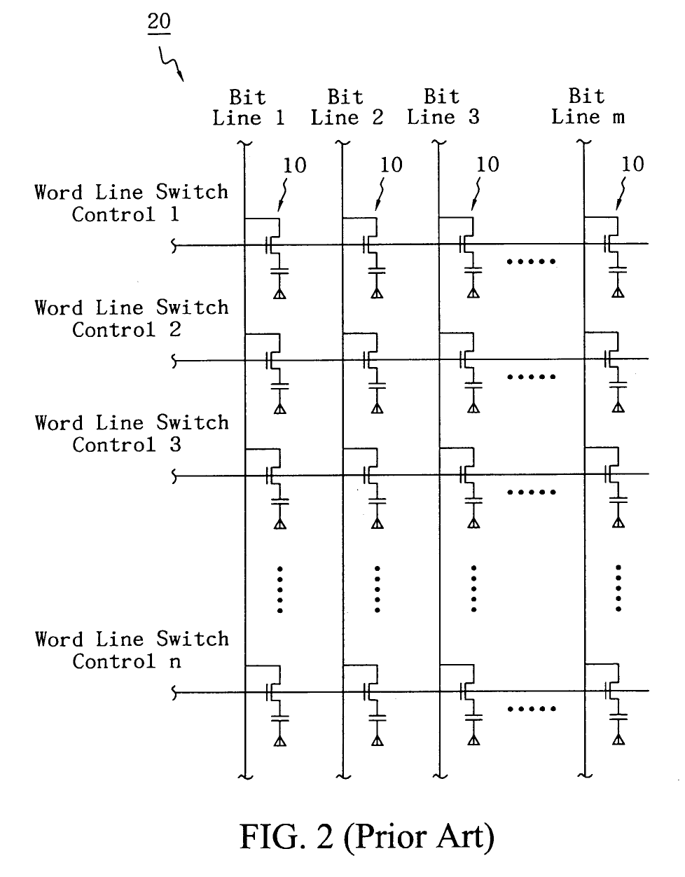

FIG. 3 shows an embodiment of the memory unit according to the present invention; and

FIG. 4 shows an embodiment of the memory circuit according to the present invention.

### DESCRIPTION OF THE PREFERRED EMBODIMENTS

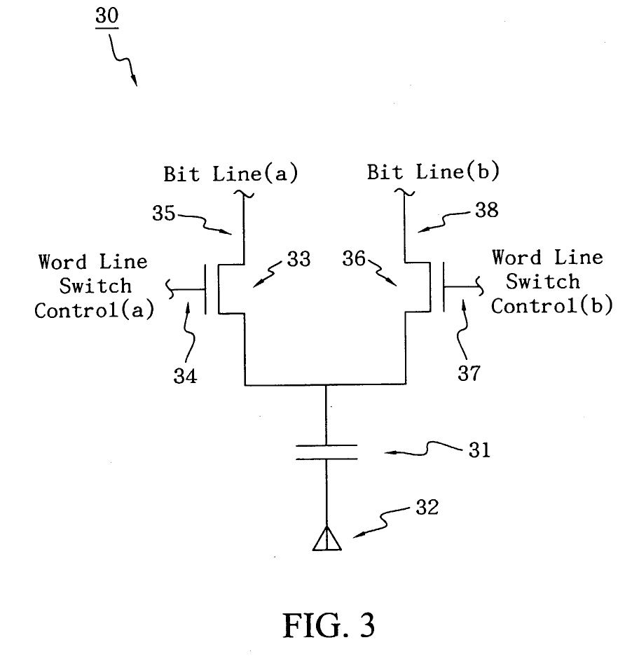

Referring to FIG. 3, the largest difference between the memory cell 30 according to the present invention and the conventional memory cell 10 is an increase of another MOS transistor, bit line and word line terminals. The memory cell 30 includes a first MOS transistor 33, a second MOS transistor 36, a bit line terminal (a) 35, a bit line terminal (b) 38, a word line terminal (a) 34, a word line terminal (b) 37, a capacitor 31, and a cell anode voltage 32. The other end of the first MOS transistor 33 and the second MOS transistor 36 opposite to the bit line terminal (a) 35 and the bit line terminal (b) 38 is connected to the capacitor 31. With the above-mentioned circuit structure, the memory cell 30 according to the present invention can allow the word line terminal (a) 34 and the word line terminal (b) 37 being activated at different times to read from or write into the capacitor 31.

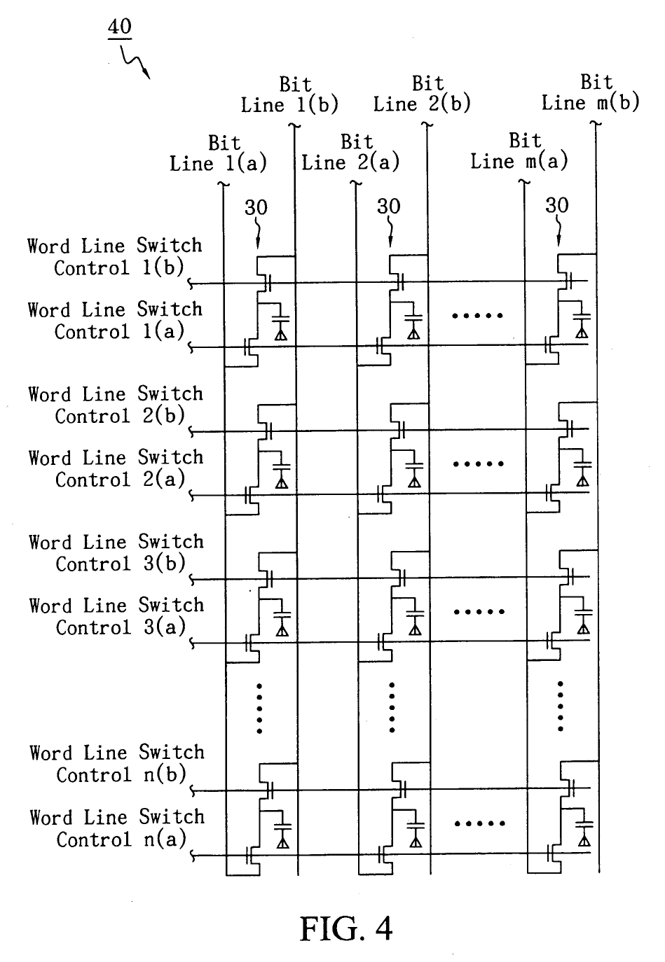

FIG. 4 is an embodiment of the memory circuit according to the present invention. The memory circuit 40 comprises memory cells with multiple bit lines 30 in an m×n matrix arrangement, 2×m bit lines, and 2×n word lines, wherein the memory cell with multiple bit lines 30 employs the circuit structure as shown in FIG. 3. The 2×m bit lines are electrically connected to the bit line terminal (a) and the bit line terminal (b) of the memory cell with multiple bit lines in vertical adjacency. The 2×n word lines are electrically connected to the word line terminal (a) and the word line terminal (b) of the memory cell with multiple bit lines in horizontal adjacency. Because the memory circuit 40 according to the present invention provides two sets of bit lines and word lines, when the same memory block (i.e. the memory cells connected to the same bit line) already has a memory cell using a word line (a) and a bit line (a), the remaining memory cells in the memory block can still use the other set of word line (b) and bit line (b) to complete the operation of memory read or write. In other words, the same memory block can allow two word lines and bit lines to be activated on different memory cells simultaneously.

In conclusion, the present invention can provide enhanced operation efficiency and throughput, thus the memory cell and the memory circuit according to the present invention can be applied to high-speed memory circuit.

The above-described embodiments of the present invention are intended to be illustrative only. Numerous alternative embodiments may be devised by those skilled in the art without departing from the scope of the following claims.

What is claimed is:

1. A memory cell with multiple bit lines, comprising:
a capacitor;
at least two transistor switches, wherein the capacitor is connected to one end of the at least two transistor switches;
at least two word line terminals for controlling the connection of the two transistor switches; and
at least two bit line terminals connected to the other end of the two transistor switches opposite the capacitor.

2. The memory cell with multiple bit lines of claim 1, wherein the transistor switches are MOS transistors.

3. The memory cell with multiple bit lines of claim 1, wherein the memory cells are SRAM cells or DRAM cells.

4. The memory cell with multiple bit lines of claim 1, wherein the memory cells are SRAM interface implemented with DRAM or DRAM with hidden external refresh commands.

5. A memory circuit with multiple bit lines, comprising:
memory cells with multiple bit lines of claim 1 arranged in an m×n matrix, wherein m and n are integers;
2×m bit lines electrically connected to the bit line terminals of the memory cells in vertical adjacency; and
2×n word lines electrically connected to the word line terminals of the memory cells in horizontal adjacency.

6. The memory circuit with multiple bit lines of claim 5, wherein the memory cells are SRAM cells or DRAM cells.

7. The memory circuit with multiple bit lines of claim 5, wherein the memory cells are SRAM interface implemented with DRAM or DRAM with hidden external refresh commands.
